(19) United States
(12) Patent Application Publication
(10) Pub. No.: US 2024/0143033 A1
(43) Pub. Date: May 2, 2024

(54) FLEXIBLE SUBSTRATE, FLEXIBLE DISPLAY DEVICE HAVING THE SAME, AND PREPARATION METHOD THEREOF

(71) Applicant: Najing Technology Corporation Limited, Hangzhou, Zhejiang (CN)

(72) Inventors: Yong DU, Hangzhou, Zhejiang (CN); Xinyan GU, Hangzhou, Zhejiang (CN)

(21) Appl. No.: 17/769,341

(22) PCT Filed: Oct. 10, 2020
(86) PCT No.: PCT/CN2020/120233

§ 371 Date: Apr. 15, 2022

(30) Foreign Application Priority Data
Oct. 16, 2019 (CN) 201910984670.4

(51) Int. Cl. G06F 1/16; H10K 59/12; H10K 59/80; H10K 77/10; H10K 102/00

(52) U.S. Cl. CPC G06F 1/1652; H10K 59/1201; H10K 59/877; H10K 77/111; H10K 2102/311; H10K 2102/351

(57) ABSTRACT

The present disclosure provides a flexible substrate, a flexible display device having the same, and a preparation method thereof. The flexible substrate includes a first flexible material layer, light extraction isolation structures, and a plurality of light extraction layers; the light extraction isolation structures are disposed on a surface of the first flexible material layer to form a plurality of light extraction regions isolated from each other between the light extraction isolation structures; the plurality of light extraction layers are disposed one-to-one respectively in at least past of the plurality of the light extraction regions, so that each of the light extraction layers corresponding to different wavelengths of incident light has different improvement ratios of light extraction efficiency when the different wavelengths of incident light passes through each of the light extraction layers.

### CROSS REFERENCE TO RELATED APPLICATIONS

This application is a national application of PCT/CN2020/120233, filed on Oct. 10, 2020. The contents of PCT/CN2020/120233 are all hereby incorporated by reference.

### TECHNICAL FIELD

The present disclosure relates to the field of optics, and in particular, to a flexible substrate, flexible display device having the same and a preparation method thereof.

### BACKGROUND

OLED or QLED displays have been used in flexible screens of mobile phones, wearable electronics and luminous clothing due to characteristics such as self-emitting, low driving voltage, high luminous efficiency, fast response time, high contrast ratio and definition, nearly 180° viewing angle, and a wide range of operated temperature. Their applications in improving black performance, wide color gamut and flexible display are anticipated to surge in the future. Quantum dots are a new technology applied in display technology. Due to quantum confinement effect, properties of quantum dots are dependent on their particle sizes. When excited by light or electricity, quantum dots can emit colored light which is related to the properties of the quantum dots, so the light emitted can be adjusted by changing the size of the quantum dots. Quantum dots have the advantages of narrow spectral linewidth and color purity. The application of quantum dots in display technology can greatly improve the color gamut of traditional displays, and enhance the color restoration capability of the displays, so quantum dots have more advantages in flexible display.

However, in the prior art flexible display devices have a relatively lower luminous efficiency, under the same luminance condition, so they need higher current density which will lead to shorter lifetime.

### SUMMARY

According to one aspect of the present disclosure, a flexible substrate is provided, including a first flexible material layer, light extraction isolation structures, which are disposed on a surface of the first flexible material layer to form a plurality of light extraction regions isolated from each other between the light extraction isolation structures; a plurality of light extraction layers, which are disposed one-to-one respectively in at least part of the plurality of the light extraction regions, so that each of the light extraction layers corresponding to the different wavelengths of incident light has different improvement ratios of light extraction efficiency when different wavelengths of incident light passes through each of the light extraction layers.

According to another aspect of the present disclosure, a flexible light-emitting device is provided, including the aforesaid flexible substrate, wherein the flexible substrate includes m light extraction layers; a light-emitting device disposed on a surface of the flexible substrate for emitting different wavelengths of light, which includes n light-emitting units; wherein, the m light extraction layers have one-to-one correspondence with m light-emitting units for improving external quantum efficiency of the m light-emitting units, n≥m, the n and the m are both positive integers.

According to another aspect of the present disclosure, a preparation method for the aforesaid flexible substrate is provided, including: S1, disposing a first flexible material layer on a substrate, and disposing light extraction isolation structures on a surface of the first flexible material layer away from the substrate to form a plurality of light extraction regions isolated from each other between the light extraction isolation structures; S2, disposing a plurality of light extraction layers in at least part of the plurality of the light extraction regions, wherein each of the light extraction layers corresponding to the different wavelengths of incident light has different improvement ratios of light extraction efficiency.

### BRIEF DESCRIPTION OF THE DRAWINGS

The drawings constituting a part of the present disclosure are used to provide a further understanding of the present disclosure, and the schematic embodiment of the present disclosure and the description thereof are for explaining the present disclosure, and does not constitute an improper limitations of the present disclosure. In the drawings:

FIG. 1 shows a sectional view of a flexible substrate according to an embodiment of the present disclosure.

FIG. 2 shows a sectional view of another flexible substrate according to an embodiment of the present disclosure.

The above drawings include the following reference signs:
10, first flexible material layer; 20, light extraction isolation structure; 30, light extraction layer, 40, second flexible material layer.

### DETAILED DESCRIPTION

It should be noted that the embodiments of the present disclosure and the features of the embodiments may be combined with each other in case of no conflict. The disclosure will be described in detail below with reference to the figures and in conjunction with the embodiments.

As used herein, the singular forms “a,” “an” and “the” are intended to include the plural forms as well, unless the context clearly indicates otherwise.

It should be understood that when an element (such as a layer, a film, a region, or a substrate) is described as being “on” another element, the element can be directly on the other element, or intervening elements may also be present.

In order to enable a person skilled in the art to have a better understanding of the solution of the present disclosure, the technical solutions in the embodiments of the present disclosure will be clearly and completely described below with reference to the figures, but obviously, the described embodiments are merely a part of the embodiments of the disclosure rather than all of the embodiments. All other embodiments obtained by a person of ordinary skill in the art based on the embodiments of the present disclosure without creative efforts should fall within the scope of the present disclosure.

It should be noted that the terms “first”, “second”, and the like in the specification and claims of the present disclosure are used to distinguish similar objects, and are not necessarily used to describe a particular order or sequence. It should be understood that the number so used may be interchangeable when appropriate to facilitate the description of embodiments of the invention disclosed herein. Furthermore, the terms “include” and “have”, as well as any variants thereof, are intended to cover a non-exclusive inclusion, for example, processes, methods, systems, products, or devices that include a series of steps or units are not necessarily limited to include those steps or units explicitly listed, and may include other steps or units not explicitly listed or inherent to such processes, methods, products or devices.

In the present disclosure, the term “D50” is the value of particle diameter at 50% in the cumulative distribution (50% of the total particles are smaller than this size).

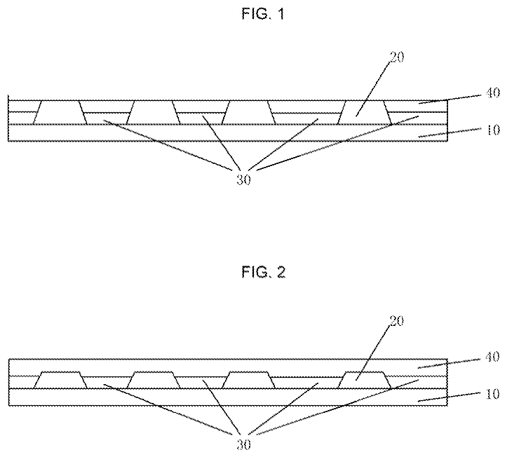

According to the background of the present disclosure, in the prior art flexible display device have relatively lower luminous efficiency, so under the same luminance, they need higher current density which will lead to shorter lifetime. In order to solve the above technical problem, the present disclosure has provided a flexible substrate, as shown in but not limited to FIGS. 1 and 2, including a first flexible material layer 10, light extraction isolation structures 20, and a plurality of light extraction layers 30, the light extraction isolation structures 20 are disposed on a surface of the first flexible material layer 10 to form a plurality of light extraction regions isolated from each other between the light extraction isolation structures 20; the plurality of light extraction layers 30 are disposed one-to-one respectively in at least part of the plurality of the light extraction regions, so that each of the light extraction layers corresponding to different wavelengths of incident light has different improvement ratios of light extraction efficiency when the different wavelengths of incident light passes through each of the light extraction layers.

It should be noted that “the plurality of light extraction layers 30 are disposed one-to-one respectively in at least part of the plurality of the light extraction regions” means that the number of the light extraction regions may be greater than or equal to the number of the light extraction layers 30, and when the number of the light extraction regions is greater than the number of the light extraction layers, them are no light extraction layers 30 in some of the light extraction regions.

The light extraction layers have different improvement ratios of light extraction efficiency corresponding to different wavelengths of incident light, so that after the flexible substrate is applied to the flexible display device, the external quantum efficiencies of light-emitting units with different wavelengths in the light-emitting device of the flexible display device can be optimized by the light extraction layers corresponding to the different wavelengths of incident light, thereby not only improving the luminous efficiency of the device, but also enabling the final external quantum efficiencies of the different light-emitting units to be close, thereby realizing even degradation and prolonging the lifetime of the flexible device. In some embodiments, the light-emitting unit can be a quantum dot electroluminescent device (QLED), or an organic electroluminescent device (OLED), or the other different kind of electroluminescent device, or an electroluminescent device combined with color conversion element.

The shapes of the light extraction isolation structures are not limited, and their cross-section shape may be trapezoidal or rectangular. The light extraction isolation structures have a specific pattern from top view (not shown), such as a weblike pattern, the mesh of the weblike pattern can be rectangular or other shapes.

The plurality of light extraction layers 30 are disposed one-to-one respectively in at least part of the plurality of light extraction regions, which means that there is no absolute one-to-one correspondence between the light extraction layers 30 and the light extraction regions, and there may be no light extraction layers 30 in some of the plurality of light extraction regions. In some embodiments, the external quantum efficiency of the light-emitting unit is quite high, them's no need for additional light extraction layer 30 to improve the external quantum efficiency of the light-emitting unit.

Each of light extraction layers 30 corresponding to different wavelengths of incident light has different improvement ratios of light extraction efficiency when the different wavelengths of incident light passes through each of the light extraction layers 30, wherein, the aforesaid different wavelengths of incident light not only can refer to different incident light having single wavelength, but also can be understood as incident light with different wavelength ranges. For example, incident light in the wavelength ranges of red light, incident light in the wavelength ranges of green light and incident light in the wavelength ranges of blue light, belong to the different wavelengths of incident light.

After preparing a flexible light-emitting device with the flexible substrate, in the flexible light-emitting device having the flexible substrate, them is one-to-one correspondence between the light extraction layers 30 and the plurality of light-emitting units, and the improvement ratios of light extraction efficiency mean the improvement ratios of external quantum efficiency of the light-emitting units. In some embodiments, a light-emitting unit with the highest initial (a flexible substrate without the light extraction layers) external quantum efficiency is defined as a first light-emitting unit, a light-emitting unit with the lowest initial external quantum efficiency is defined as a third light-emitting unit, and a light-emitting unit with the initial external quantum efficiency between the highest initial external quantum efficiency and the lowest initial external quantum efficiency is defined as a second light-emitting unit, an improvement ratio of the external quantum efficiency of the first light-emitting unit by the light extraction layer 30 is X₁, an improvement ratio of the external quantum efficiency of the second light-emitting unit by the light extraction layer 30 is X₂, and an improvement ratio of the external quantum efficiency of the third light-emitting unit by the light extraction layer 30 is X₃, wherein the X₁, the X₂ and the X₃ are not equal, and X_{N}=(Q₂−Q₁)/Q₁ is defined, wherein, the N is any natural number from 1 to 3, the Q₁ is the initial external quantum efficiency of the corresponding light-emitting unit, and the Q₂ is the actual external quantum efficiency of the corresponding light-emitting unit.

In some embodiments, after preparing a flexible light-emitting device with the flexible substrate, in the flexible light-emitting device having the flexible substrate, the actual external quantum efficiency deviations among each of the light-emitting units are within ±15%. Specifically, the actual external quantum efficiency deviation of each light-emitting unit=(the actual external quantum efficiency of each light-emitting unit—the average value of the actual external quantum efficiency of all light-emitting units) the average value of the actual external quantum efficiency of all light-emitting units.

In some embodiments, in the flexible light-emitting device having the flexible substrate, the actual external quantum efficiency deviations among each of the light-emitting units are within ±30%.

In some embodiments, the actual external quantum efficiency deviations among each of the light-emitting units are within ±10%.

In some embodiments, the actual external quantum efficiency deviations among each of the light-emitting units are within ±5%.

In order to enable the light extraction layers 30 to have different improvement ratios of light extraction efficiency corresponding to different wavelengths of incident light, in some embodiments, a thickness of each of light extraction layers corresponding to different wavelengths of incident light is different; in other embodiments, each of the light extraction layers 30 is a light extraction layer with scattering particles, and the thicknesses of the different light extraction layers are between 0.8 μm to 3 μm.

In some embodiments, the light extraction layers 30 corresponding to the same wavelength of incident light are disposed repeatedly on the flexible substrate, for example, a plurality of same light extraction layers corresponding to red incident light, a plurality of same light extraction layers corresponding to green incident light, or a plurality of same light extraction layers corresponding to blue incident light.

In some embodiments, the flexible substrate includes three or more kinds of light extraction layers 30 corresponding to different wavelengths of incident light.

In a preferred embodiment, the different wavelengths of incident light includes a first wavelength of incident light, a second wavelength of incident light and a third wavelength of incident light, wherein, the first wavelength of incident light is red light, the second wavelength of incident light is green light, and the third wavelength of incident light is blue light.

In some embodiments, each light extraction layer 30 may be a light extraction layer with scattering particles, and in order to enable the light extraction layers 30 to have different improvement ratios of light extraction efficiency corresponding to different wavelengths of incident light, D50 of the scattering particles in the light extraction layer 30 corresponding to the first wavelength of incident light is preferably between 300 to 325 nm, but is not limited thereto; D50 of the scattering particles in the light extraction layer 30 corresponding to the second wavelength of incident light is preferably between 250 to 275 nm, but is not limited thereto; and D50 of the scattering particles in the light extraction layer 30 corresponding to the third wavelength of incident light is preferably between 215 to 250 nm, but is not limited thereto.

In some embodiments, the flexible substrate may further include second flexible material layers 40, which are disposed on a surface of each light extraction layer 30 away from the first flexible material layer 10 and are used to be flush with the light extraction isolation structures 20 to planarize the surface of the flexible substrate, as shown in FIG. 1. In other embodiments, a second flexible material layer 40 may also be disposed on a surface of each light extraction layer 30 and a surface of each of the light extraction isolation structures 20 away from the first flexible material layer 10, in this case the second flexible material layer 40 covers both of the light extraction layers 30 and the light extraction isolation structures 20 to planarize the surface of the flexible substrate, as shown in FIG. 2.

In the flexible substrate of the present disclosure, those skilled in the art can reasonably select the materials of the first flexible material layer 10, the second flexible material layer 40, and the light extraction isolation structures 20 according to the prior art, for example, the material forming at least one of the first flexible material layer 10 and the second flexible material layer 40 can be a polymeric material such as polyimide, and the material forming the light extraction isolation structures 20 can be a photoresist, but is not limited thereto.

In some embodiments, a thickness of at least one of the first flexible material layer 10 and the second flexible material layer 40 is about 15 μm, a thickness of the light extraction isolation structure 20 is controlled between 0.8 μm to 3 μm, a thickness of each light extraction layer can be different and the thickness of each light extraction layer is between 0.8 μm to 3 pin, and the flexible substrate finally has a total thickness of 30 μm.

According to another aspect of the present disclosure, a flexible light-emitting device including a flexible substrate is provided, a light-emitting device disposed on a surface of the flexible substrate, wherein the light-emitting device includes n light-emitting units for emitting different wavelengths of light, and m light extraction layers 30 have one-to-one correspondence with m light-emitting units for improving external quantum efficiency of each of the light-emitting units, wherein, n≥m, the n and the m are both positive integers. Specifically, the light-emitting device is disposed on the surface of the flexible substrate away from the first flexible material layer 10.

In the aforesaid flexible light-emitting device, external quantum efficiencies of the different light-emitting units can be optimized by providing the different light extraction layers for the different light-emitting units, which enables the final external quantum efficiencies of the different light-emitting units to be close, thereby realizing even degradation and prolonging the lifetime of the flexible light-emitting device.

The m light extraction layers 30 have one-to-one correspondence with the m light-emitting units, wherein, n≥m, the n and the m are both positive integers, which means that there is no absolute one-to-one correspondence between the light extraction layers 30 and the light-emitting units, and the light extraction layers 30 can be disposed on a surface of partial light-emitting units. In some embodiments, the flexible light-emitting device containing three kinds (red, green, blue) of light-emitting units can only have the light extraction layers corresponding to blue light-emitting units, but do not have the light extraction layers corresponding to red and green light-emitting units.

In some embodiments, the light-emitting device can be a QLED device or an OLED device. However, it is not limited thereto, and those skilled in the art can choose the proper type of the light-emitting device according to actual needs.

In some embodiments, the flexible light-emitting device of the present disclosure may further include a TFT (thin film transistor) circuit, which is disposed on a surface of the flexible substrate away from the first flexible material layer 10. The TFT electrically controls the light-emitting units to emit light.

According to another aspect of the present disclosure, a preparation method for the above-described flexible substrate is also provided, including the following steps: S1, a first flexible material layer 10 is disposed on a substrate, and light extraction isolation structures 20 are disposed on a surface of the first flexible material layer 10 away from the substrate to form a plurality of light extraction regions isolated from each other between the light extraction isolation structures 20; S2, a plurality of light extraction layers 30 are disposed in at least part of the plurality of the light extraction regions, and each of the light extraction layers corresponding to different wavelengths of incident light has different improvement ratios of light extraction efficiency.

An exemplary embodiment of the preparation method of the flexible substrate provided in accordance with the present disclosure will be described in more detail below. However, these exemplary embodiments may be implemented in a variety of different forms, and should not be construed as being limited to the embodiments set forth herein. It should be understood that these embodiments are provided to make the disclosure of the present disclosure thoroughly communicatively to those of ordinary skill in the art.

First, the S1: a first flexible material layer 10 is disposed on a substrate, and light extraction isolation structures 20 are disposed on a surface of the first flexible material layer 10 away from the substrate to form a plurality of light extraction regions isolated from each other between the light extraction isolation structures 20.

In some embodiments, in the S1, the first flexible material layer 10 can be disposed by using any one of slit coating, spray coating and printing process, the surface of the first flexible material layer 10 is coated with a photoresist resin, and the light extraction isolation structures 20 are obtained by photolithography process.

In some embodiments, a preparation process of the first flexible material layer 10 may specifically include: a layer of polyimide (PI) is formed on a rigid substrate by wet process like slit coating, spray coating or printing process, etc. Preferably, the layer is formed by slit coating, using PI coating solution and adjusting parameters of the PI coating solution, such as viscosity p, surface tension a, and density p; controlling process parameters, such as coating gap distance H and slit coating die width w, coating speed v, coating liquid flow rate Q, etc., to make the film layer even; then the substrate is vacuum dried, and the temperature is between 50 to 120° C., the pressure is less than or equal to 50 Pa. After drying, a thickness of the first flexible material layer 10 is preferably about 15 μm.

In some embodiments, a preparation process of the light extraction isolation structures 20 can include: a photoresist resin, such as photo-sensitive polyimide, is used to form patterned isolation walls on a substrate through a photolithography process, and a plurality of open areas surrounded by the isolation walls constitute the light extraction regions between the light extraction isolation structures 20. In some embodiments, a thickness of the light extraction isolation structures 20 is between 0.8 μm to 3 μm.

After the step of forming the light extraction isolation structures 20, the S2 is performed: a plurality of light extraction layers 30 are disposed in at least part of the plurality of the light extraction regions, and each of the light extraction layers corresponding to different wavelengths of incident light has different improvement ratios of light extraction efficiency. That is, a plurality of light extraction layers 30 are disposed one-on-one respectively in at least part of the plurality of the light extraction regions, and each of the light extraction layers 30 corresponding to the different wavelengths of incident light has different improvement ratios of light extraction efficiency.

In some embodiments, in the S2, the light extraction layers 30 can be formed by any one of slit coating, spray coating and printing process, preferably, using the printing process. A thickness of each light extraction layer can be different, respectively 0.8 μm to 3 μm. In some embodiments, the thickness (height) of the light extraction isolation structures is greater than or equal to the thickness of the light extraction layers.

In some embodiments, a preparation process of the light extraction layers 30 can include: different light extraction inks with different scattering particles are printed in the light extraction regions, corresponding to the R, G and B pixels of the light-emitting device respectively, and then the light extraction inks are dried to form the light extraction layers, and the temperature of vacuum drying is higher than 80° C. In some embodiments, the light extraction material can get smoothed naturally to form a film, specifically, the light extraction material is applied to the light extraction regions by conventional processes and left to dry, and the solvent is volatilized (can be used with heating and vacuum to assist drying), then it is UV cured and heated, common heating or vacuum heating technology can be used to ensure that the solvent is removed and the UV adhesive is cured completely. In other embodiments, the light extraction material is applied to the light extraction regions by conventional processes and left to dry, and after its solvent is volatilized (drying process can be assisted with vacuum), then it is cured by heating.

In some embodiments, raw material including scattering particles, additive, curable adhesive and a first solvent are provided in the light extraction regions, then they're cured and dried to form the light extraction layers 30. In some embodiments, the raw material contain 1 to 30 parts of scattering particles by weight, 0.1 to 10 parts of additive by weight, and 1 to 15 parts of curable adhesive.

In some embodiments, the solvent in the raw material may be a single solvent or a mixed solvent. When the solvent is a single solvent, the boiling point of a single solvent is greater than 140° C. In other embodiments, the boiling point of the single solvent is greater than 180° C., preferably greater than 200° C.; when the solvent is a mixed solvent, a component with the lowest boiling point in the mixed solvent has a boiling point of greater than 100° C., a component with the highest boiling point in the mixed solvent has a boiling point of less than 300° C., and the average boiling point of the mixed solvent is greater than 140° C.; in other embodiments, the average boiling point of the mixed solvent is greater than 180° C., preferably greater than 200° C.

In some embodiments, in order to optimize the improvement ratios of light extraction efficiency of the light extraction layers 30, a refractive index of the scattering particles is 1.45 to 26, and a refractive index of the cured adhesive is 1.45 to 1.8, a refractive index of the additive is 1.45 to 1.7. In some embodiments, the scattering particles in the light extraction layers 30 include, but are not limited to, one or more of zinc oxide, alumina, zirconia, and titanium oxide, and the like.

In some embodiments, the additive is selected from at least one or a combination of dispersant, viscosity modifier, and coupling agent. The dispersant can be selected from at least one of a polymer dispersant and a small molecule dispersant, and the polymer dispersant may be selected from one or a combination of a polyether polyol, a polyether, and the like; the small molecule dispersant may be selected from one or a combination of ethylene bis-stearamide, sodium dodecyl sulfate, and the like. The viscosity modifier can be a polymer, such as one or a combination of poly (methyl methacrylate) (PMMA), polystyrene (PS), polyisobutylene (PIB), poly (9-vinylcarbazole) (PVK), and the like. The coupling agent can be a silane coupling agent, such as one or a combination of triethoxyvinylsilane, 3-(trimethoxysilyl) propyl methacrylate, and the like. The refractive index of the additive is different from the refractive index of the scattering particles, preferably, the refractive index difference between the additive and the scattering particles is quite large.

In some embodiments, the raw material for the formation of light extraction layers 30 also include a solvent, and the solvent may be selected from one or a combination of aromatic hydrocarbon, ester, ether, alkane, alcohol, ether alcohol, etc. The aromatic hydrocarbon can be selected from one or a combination of xylene, mesitylene, and the like; the ester may be selected from one or a combination of methyl benzoate, ethyl benzoate, diethyl glutarate, and the like; the ether may be selected from one or a combination of anisole, phenetole, and the like; the alkane may be selected from one or a combination of decane, undecane, dodecane, and the like; the alcohol can be selected from one or a combination of heptanol, octanol, dodecanol, and the like; the ether alcohol may be selected from one or a combination of tripropylene glycol monomethyl ether, 1-methoxy-2-propanol, diethylene glycol, and the like. The solvent may also be selected from other types besides the above mentioned, and those skilled in the art can reasonably select the specific species of the solvent according to the other ingredients in the raw material.

In some embodiments, after the step of forming the light extraction layers 30, the preparation method further includes the step: S3, a second flexible material layer 40 is disposed on a surface of the light extraction layers 30 and the light extraction isolation structures 20 away from the first flexible material layer 10, as shown in FIG. 2.

In some embodiments, a preparation process of the second flexible material layer 40 may specifically include: a second polyimide layer is disposed on the light extraction layers 30 and the light extraction isolation structures 20 by wet process like slit coating, spray coating and printing process, etc. Preferably, the layer is formed by slit coating, using PI coating solution and adjusting parameters of the PI coating solution, such as viscosity μ, surface tension σ, and density ρ; controlling process parameters, such as coating gap distance H and slit coating die width w, coating speed v, coating liquid flow rate Q, etc., to make the film layer even; then the substrate is vacuum dried, and the temperature is between 50 to 120° C., the pressure is less than or equal to 50 Pa. In some embodiments, a thickness of the second flexible material layer 40 is preferably about 15 μm after drying, so as to form a PI flexible substrate with a total thickness of 30 μm.

In some embodiments, after the S2, the preparation method further includes a step: S3′, second flexible material layers are disposed on a surface of each of the light extraction layers away from the first flexible material layer, as shown in FIG. 1.

In some embodiments, thin film transistors and pixel isolation structures are disposed on the flexible substrate in sequence, thus being suitable for flexible displays.

The flexible substrate, its preparation method, and the flexible display device with the flexible substrate are further described below in combination with the examples and the comparative example.

### Example 1

This example provides a preparation method of a flexible display device, including the steps of: A layer of polyimide (PI) was disposed on a rigid substrate by slit coating, then vacuum dried, the baking temperature was 100° C., the pressure was 50 Pa, and a first flexible material layer was formed with a thickness of 15 μm.

A photoresist such as photo-sensitive polyimide was disposed on the first flexible material layer by photolithography process to form patterned isolation walls (banks) as light extraction isolation structures, and 96×3×64 light extraction regions were formed between the light extraction isolation structures. The thickness of the light extraction isolation structures was controlled within 2 μm.

Different light extraction inks with different scattering particle sizes were printed by DMP2831 inkjet printer, which corresponding to R, G, B pixels (light-emitting units emit red light, green light, and blue light, respectively) of electroluminescent device, respectively. The printed inks were first vacuum dried at 100° C. then UV cured, after baked for 30 min at 100° C., light extraction layers were formed in the light extraction regions, and the thicknesses of the light extraction layers corresponding to R, G, and B pixels were all 1.5 μm.

The formulation of the above-described light extraction inks were: 5 wt % zirconium dioxide as scattering particles (refractive index n=2.2), 0.5 wt % PVK (n=1.63) as viscosity modifier, 5 wt % Vitralit 6108 (n=1.48) as UV adhesive, 0.5 wt % Solsperse32000 (n=1.48) as dispersant, the remaining components were 60 wt % ethyl benzoate and 29 wt % anisole (boiling point of ethyl benzoate=212° C., density=1.05 g/cm³; boiling point of anisole=154° C., density=0.995 g/cm³; calculated average boiling point (respective boiling point×volume percentage=1924° C.). D50 of the scattering particles in the light extraction layer corresponding to R, G, B pixels were 310 nm, 260 nm and 240 nm, respectively.

A second polyimide (PI) layer was disposed on the light extraction isolation structures and the light extraction layers, then the substrate was vacuum dried at the temperature of 100° C., the vacuum pressure was 50 Pa, and a second flexible material layer having a thickness of 15 μm was formed, and the PI flexible substrate was obtained.

TFT circuit and QLED electroluminescent device were fabricated on the PI flexible substrate, then encapsulated by thin film encapsulation technology. After detached from the rigid substrate by laser lift-off technology, a flexible display device was obtained.

### Example 2

The difference between this example and Example 1 is:
The scattering particles were rutile titanium dioxide (n=26).

### Example 3

The differences between this example and Example 1 are:
The thicknesses of the light extraction layers corresponding to R, G, and B pixels in the QLED electroluminescent device were different, the thickness of the light extraction layers corresponding to red pixels was 0.8 μm, the thickness of the light extraction layers corresponding to green pixels was 1.5 μm, and the thickness of the light extraction layers corresponding to blue pixels was 3 μm.

### Example 4

The differences between this example and Example 1 are:
D50 of the scattering particles corresponding to R, G, and B pixels were 300 nm, 250 nm, and 215 nm, respectively.

### Example 5

The differences between this example and Example 1 are:
D50 of the scattering particles corresponding to R, G, and B pixels were 325 nm, 275 nm, and 250 nm, respectively.

### Example 6

The differences between this example and Example 1 are:
The light extraction ink contained 30 wt % scattering particles, 10 wt % additive (viscosity modifier and dispersant), 15 wt % UV adhesive by weight.

### Example 7

The differences between this example and Example 1 are:
The light extraction ink contained 1 wt % scattering particles, 0.1 wt % additive (viscosity modifier and dispersant), 1 wt % UV adhesive by weight.

### Example 8

The differences between this example and Example 1 are:
The mixed solvent in the light extraction ink included 30 wt % 1, 3-dimethoxybenzene and 59 wt % toluene by weight, and the average boiling point of the mixed solvent was 142.1° C.

### Example 9

The differences between this example and Example 1 are:
The mixed solvent in the light extraction ink included 60 wt % phenylcyclohexane (density=0.95 g/cm³, boiling point=2426° C.) and 29 wt % ethyl benzoate (density=1.05 g/cm³, boiling point=212° C.) by weight, and the average boiling point of the mixed solvent was 233.3° C.

### Example 10

The differences between this example and Example 1 are:
The scattering particles in the light extraction ink were aluminum oxide (refractive index=1.76), the UV adhesive was NOA1625 (refractive index=1.62), the viscosity modifier was poly (methyl methacrylate) (refractive index=1.48), and the dispersant was Solsperse36600 (refractive index=1.5).

### Example 11

The differences between this example and Example 1 are:
The scattering particles in the light extraction ink were silicon dioxide (refractive index=1.45), the UV adhesive was CP5-UV (refractive index=1.78), the viscosity modifier was polystyrene (refractive index=1.57), and the dispersant was Solsperse38500 (refractive index=1.5).

### Comparative Example 1

The differences of the light-emitting devices between this comparative example and Example 1 are:
The flexible substrate was only composed of two layers of polyimide (PI).

Test method for external quantum efficiency:
The current density-voltage curve of the light-emitting device was measured by Keithley2400, and the luminance of the light-emitting device was determined by spectrometer (QE-Pro) combined with the integrating sphere (FOIS-1). The external quantum efficiency of the light-emitting device was calculated based on the measured current density and the luminance.

The R, G, B pixels of the light-emitting devices of the above Examples 1 to 11 and Comparative Example 1 were operated respectively and their external quantum efficiencies were tested accordingly, and the results are shown in the following table.

| Items | R: EQE % | G: EQE % | B: EQE % |
|---|---|---|---|
| Example 1 | 18.7 | 17.3 | 17.1 |
| Example 2 | 20.1 | 20.9 | 19.5 |
| Example 3 | 18.1 | 17.5 | 18 |
| Example 4 | 18.5 | 17.5 | 16.9 |
| Example 5 | 18.3 | 17.8 | 17 |
| Example 6 | 16.7 | 17.1 | 15.9 |
| Example 7 | 19.1 | 19.9 | 18.3 |
| Example 8 | 18.5 | 17.4 | 17.3 |
| Example 9 | 18.6 | 17.2 | 17.5 |
| Example 10 | 17.2 | 18 | 16.4 |
| Example 11 | 15.1 | 16.1 | 14.8 |
| Comparative | 10.1 | 9.5 | 7.8 |
| Example 1 | | | |

It can be seen from the test data of the above table, without light extraction layer, the external quantum efficiencies of R, G, and B pixels of Comparative Example 1 were much lower than those of Examples 1 to 11, and the deviations of external quantum efficiency among different color pixels were large; after adding the different light extraction layers, although the external quantum efficiency of the same color pixels among the various examples was different, the deviations of external quantum efficiency among R, G, and B pixels of the same device were much smaller than those of Comparative Example 1, which can make the device degrade evenly.

From the above description, it can be seen that the examples of the present disclosure achieve the following technical effects:
The light extraction layers have different improvement ratios of light extraction efficiency corresponding to different wavelengths of incident light, so that after the flexible substrate is applied to the flexible display device, the external quantum efficiencies of different light-emitting units of the flexible display can be optimized, thereby not only improving the luminous efficiency of the device, but also enabling the final external quantum efficiency of different light-emitting units to be close, thereby realizing even degradation and prolonging the lifetime of the flexible device.

The above are only the preferable examples of the disclosure, and have no intention to limit the disclosure, it is to be noted by those skilled in the art that the disclosure may have various modifications and variations. Any modifications, equivalent replacements, improvements and the like made within the spirit and principle of the disclosure shall fall within the scope of protection of the disclosure.

1. A flexible substrate, comprising:
a first flexible material layer;
light extraction isolation structures, which are disposed on a surface of the first flexible material layer to form a plurality of light extraction regions isolated from each other between the light extraction isolation structures;
a plurality of light extraction layers, which are disposed one-to-one respectively in at least part of the plurality of the light extraction regions, so that each of the light extraction layers corresponding to the different wavelengths of incident light has different improvement ratios of light extraction efficiency when different wavelengths of incident light passes through each of the light extraction layers.

2. The flexible substrate according to claim 1, the flexible substrate further comprising a second flexible material layer, which is disposed on a surface of each of the light extraction layers away from the first flexible material layer, or disposed on a surface of each of the light extraction layer and a surface of each of the light extraction isolation structures away from the first flexible material layer.

3. The flexible substrate according to claim 1, wherein a thickness of each of the light extraction layers corresponding to the different wavelengths of incident light is different.

4. The flexible substrate according to claim 3, wherein each of the light extraction layers is a light extraction layer having scattering particles, and the thickness of the different light extraction layers is 0.8 μm to 3 μm respectively.

5. The flexible substrate according to claim 1, wherein, the different wavelengths of incident light comprises a first wavelength of incident light, a second wavelength of incident light and a third wavelength of incident light, the first wavelength of incident light is red light, the second wavelength of incident light is green light, and the third wavelength of the incident light is blue light.

6. The flexible substrate according to claim 5, wherein, each of the light extraction layers is a light extraction layer having scattering particles, D50 of the scattering particles in the light extraction layer corresponding to the first wavelength of incident light is 300 nm to 325 nm.

7. The flexible substrate according to claim 6, wherein, D50 of the scattering particles in the light extraction layer corresponding to the second wavelength of incident light is 250 nm to 275 nm.

8. The flexible substrate according to claim 6, wherein, D50 of the scattering particles in the light extraction layer corresponding to the third wavelength of incident light is 215 nm to 250 nm.

9. A flexible light-emitting device, comprising:
a flexible substrate according to claim 1, wherein the flexible substrate comprises m light extraction layers;
a light-emitting device disposed on a surface of the flexible substrate for emitting different wavelengths of light, which comprises n light-emitting units; wherein, the m light extraction layers have one-to-one correspondence with m light-emitting units for improving external quantum efficiency of the m light-emitting units, n≥m, the n and the m are both positive integers.

10. The flexible light-emitting device according to claim 9, wherein the light-emitting device is an OLED device or a QLED device.

11. A preparation method for the flexible substrate, comprising:
S1, disposing a first flexible material layer on a substrate, and disposing light extraction isolation structures on a surface of the first flexible material layer away from the substrate to form a plurality of light extraction regions isolated from each other between the light extraction isolation structures;
S2, disposing a plurality of light extraction layers in at least part of the plurality of the light extraction regions, wherein each of the light extraction layers corresponding to the different wavelengths of incident light has different improvement ratios of light extraction efficiency.

12. The preparation method according to claim 11, wherein, in the step S1, a process of disposing the first flexible material layer is selected from any one of coating process, spraying process and printing process, a photoresist is coated on the surface of the first flexible material layer and a photolithography process is used to obtain the light extraction isolation structures.

13. The preparation method according to claim 11, wherein, in the step S2, a process of preparing the light extraction layers is selected from any one of coating process, spraying process and printing process.

14. The preparation method according to claim 11, disposing raw material comprising scattering particles, an additive, a curable adhesive and a first solvent in the light extraction region, performing a curing reaction and drying to form the light extraction layer.

15. The preparation method according to claim 14, wherein, parts by weight, in the raw material, the scattering particles are 1 to 30 parts, the additive is 0.1 to 10 parts, and the curable adhesive is 1 to 15 parts.

16. The preparation method according to claim 14, wherein, the solvent is a single solvent having a boiling point greater than 140° C.; or
the solvent is a mixed solvent, the lowest boiling point of component of the mixed solvent is greater than 100° C., the highest boiling point of the component of the mixed solvent is less than 300° C., and an average boiling point of the mixed solvent is greater than 140° C..

17. The preparation method according to claim 14, wherein, a refractive index of the scattering particles is 1.45 to 2.6, a refractive index of the curable adhesive is 1.45 to 1.8, and a refractive index of the additive is 1.45 to 1.7.

18. The preparation method according to claim 14, wherein, the additive is selected from one or a combination of a dispersant, a viscosity modifier and a coupling agent.

19. The preparation method according to claim 11, after the step S2, further comprising the following step:
S3, disposing a second flexible material layer on a surface of each of the light extraction layers and the light extraction isolation structures away from the first flexible material layer.

20. The preparation method according to claim 11, after the step S2, further comprising the following step:
S3′, disposing second flexible material layers on a surface of each of the light extraction layers away from the first flexible material layer.
